(19) United States
(12) Patent Application Publication
(10) Pub. No.: US 2025/0316513 A1
(43) Pub. Date: Oct. 9, 2025

(54) SUBSTRATE PROCESSING SYSTEM

(71) Applicant: Tokyo Electron Limited, Tokyo (JP)

(72) Inventor: Norihiko AMIKURA, Miyagi (JP)

(73) Assignee: Tokyo Electron Limited, Tokyo (JP)

(21) Appl. No.: 19/095,065

(22) Filed: Mar. 31, 2025

(30) Foreign Application Priority Data
Apr. 3, 2024 (JP) 2024-060050

(51) Int. Cl. H01L 21/677; H01L 21/687; H02N 15/00

(52) U.S. Cl. CPC H01L 21/67709; H01L 21/67712; H01L 21/68707; H02N 15/00

(57) ABSTRACT

Provided is a substrate processing system including a load port disposed at a first height, a plurality of upper magnetic levitation type vacuum transport units disposed at a second height, a plurality of upper substrate processing modules, a plurality of lower magnetic levitation type vacuum transport units disposed at a third height lower than the second height, a plurality of lower substrate processing modules, and a load lock module configured to switch an internal environment between an atmospheric environment and a vacuum environment.

### CROSS-REFERENCE TO RELATED APPLICATION

The present application claims priority under 35 U.S.C. § 119 to Japanese patent application No. 2024-060050 filed on Apr. 3, 2024, the entire contents of which are incorporated herein by reference.

### BACKGROUND

### Field

An exemplary embodiment of the present disclosure relates to a substrate processing system.

### Description of Related Art

US2023/0085667A1 discloses a magnetic levitation transport apparatus that transports a substrate between a vacuum transport chamber and a processing chamber of a substrate processing system.

### SUMMARY

In one exemplary embodiment of the present disclosure, there is provided a substrate processing system including: a load port disposed at a first height; a plurality of upper magnetic levitation type vacuum transport units disposed at a second height, the plurality of upper magnetic levitation type vacuum transport units being connected in a horizontal direction along a first direction; a plurality of upper substrate processing modules, each of the upper substrate processing modules being connected to any of the plurality of upper magnetic levitation type vacuum transport units; a plurality of lower magnetic levitation type vacuum transport units disposed at a third height lower than the second height, the plurality of lower magnetic levitation type vacuum transport units being connected in the horizontal direction along the first direction; a plurality of lower substrate processing modules, each of the lower substrate processing modules being connected to any of the plurality of lower magnetic levitation type vacuum transport units; and a load lock module configured to switch an internal environment between an atmospheric environment and a vacuum environment, the load lock module being configured to transport at least one substrate between the load lock module and a substrate accommodation container on the load port under the atmospheric environment, transport at least one substrate in a vertical direction, transport at least one substrate between the load lock module and any of the plurality of upper magnetic levitation type vacuum transport units under the vacuum environment, and transport at least one substrate between the load lock module and any of the plurality of lower magnetic levitation type vacuum transport units under the vacuum environment.

### BRIEF DESCRIPTION OF DRAWINGS

FIG. 1 is a diagram for describing an example of a substrate processing system 1.

FIG. 2 is a diagram for describing an example of the substrate processing system 1.

FIG. 3A is a diagram for describing an example of a transport operation of the substrate processing system 1.

FIG. 3B is a diagram for describing an example of the transport operation of the substrate processing system 1.

FIG. 3C is a diagram for describing an example of the transport operation of the substrate processing system 1.

FIG. 3D is a diagram for describing an example of the transport operation of the substrate processing system 1.

FIG. 3E is a diagram for describing an example of the transport operation of the substrate processing system 1.

FIG. 3F is a diagram for describing an example of the transport operation of the substrate processing system 1.

FIG. 4 is a diagram for describing an apparatus layout of the substrate processing system 1.

FIG. 5A is a diagram for describing another example of the apparatus layout of the substrate processing system 1.

FIG. 5B is a diagram for describing another example of the apparatus layout of the substrate processing system 1.

FIG. 6 is a diagram for describing another example of an upper substrate processing module and a lower substrate processing module.

FIG. 7 is a diagram for describing another example of the upper vacuum transport unit and the lower vacuum transport unit.

FIG. 8 is a diagram for describing another example of the upper vacuum transport unit and the lower vacuum transport unit.

FIG. 9 is a diagram for describing another example of the upper vacuum transport unit and the lower vacuum transport unit.

### DETAILED DESCRIPTION

Hereinafter, each embodiment of the present disclosure will be described.

In one exemplary embodiment, there is provided a substrate processing system including: a load port disposed at a first height; a plurality of upper magnetic levitation type vacuum transport units disposed at a second height, the plurality of upper magnetic levitation type vacuum transport units being connected in a horizontal direction along a first direction; a plurality of upper substrate processing modules, each of the upper substrate processing modules being connected to any of the plurality of upper magnetic levitation type vacuum transport units; a plurality of lower magnetic levitation type vacuum transport units disposed at a third height lower than the second height, the plurality of lower magnetic levitation type vacuum transport units being connected in the horizontal direction along the first direction; a plurality of lower substrate processing modules, each of the lower substrate processing modules being connected to any of the plurality of lower magnetic levitation type vacuum transport units; and a load lock module configured to switch an internal environment between an atmospheric environment and a vacuum environment, the load lock module being configured to transport at least one substrate between the load lock module and a substrate accommodation container on the load port under the atmospheric environment, transport at least one substrate in a vertical direction, transport at least one substrate between the load lock module and any of the plurality of upper magnetic levitation type vacuum transport units under the vacuum environment, and transport at least one substrate between the load lock module and any of the plurality of lower magnetic levitation type vacuum transport units under the vacuum environment.

In one exemplary embodiment, the first height is higher than the second height.

In one exemplary embodiment, the load lock module is connected to any of the plurality of upper magnetic levitation type vacuum transport units on a first side surface, and is connected to any of the plurality of lower magnetic levitation type vacuum transport units on the first side surface.

In one exemplary embodiment, the load lock module is connected to the load port on the first side surface.

In one exemplary embodiment, the substrate processing apparatus further includes a vertical transport robot disposed in the load lock module, in which the vertical transport robot is configured to transport a stack of a plurality of substrates between the load lock module and the substrate accommodation container on the load port, and to transport the stack of the plurality of substrates in the vertical direction.

In one exemplary embodiment, the load lock module includes a vertical plane motor extending in the vertical direction, and the vertical transport robot is configured to move in the vertical direction while being magnetically levitated on the vertical plane motor to transport the stack of the plurality of substrates in the vertical direction.

In one exemplary embodiment, each of the plurality of upper magnetic levitation type vacuum transport units includes an upper horizontal plane motor extending in the horizontal direction, and the substrate processing system further includes an upper horizontal transport robot, and the upper horizontal transport robot is configured to move in the horizontal direction while being magnetically levitated on the upper horizontal plane motor to transport at least one substrate between the load lock module and the plurality of upper substrate processing modules.

In one exemplary embodiment, each of the plurality of lower magnetic levitation type vacuum transport units includes a lower horizontal plane motor extending in the horizontal direction, and the substrate processing system further includes a lower horizontal transport robot, and the lower horizontal transport robot is configured to move in the horizontal direction while being magnetically levitated on the lower horizontal plane motor to transport at least one substrate between the load lock module and the plurality of lower substrate processing modules.

In one exemplary embodiment, each of the plurality of upper magnetic levitation type vacuum transport units includes an upper horizontal plane motor extending in the horizontal direction, and the substrate processing system further includes a plurality of upper horizontal transport robots, and the plurality of upper horizontal transport robots are configured to move in the horizontal direction while being magnetically levitated on the upper horizontal plane motor to transport the plurality of substrates between the load lock module and the plurality of upper substrate processing modules at the same time.

In one exemplary embodiment, each of the plurality of lower magnetic levitation type vacuum transport units includes a lower horizontal plane motor extending in the horizontal direction, and the substrate processing system further includes a plurality of lower horizontal transport robots, and the plurality of lower horizontal transport robots are configured to move in the horizontal direction while being magnetically levitated on the lower horizontal plane motor to transport the plurality of substrates between the load lock module and the plurality of lower substrate processing modules at the same time.

In one exemplary embodiment, at least one of the plurality of upper substrate processing modules and the plurality of lower substrate processing modules includes a chamber configured to process four substrates at the same time.

In one exemplary embodiment, at least one of the plurality of upper substrate processing modules and the plurality of lower substrate processing modules includes a chamber configured to process two substrates at the same time.

In one exemplary embodiment, at least one chamber of the plurality of upper substrate processing modules and at least one chamber of the plurality of lower substrate processing modules are connected to the same gas supply portion.

In one exemplary embodiment, at least one chamber of the plurality of upper substrate processing modules and at least one chamber of the plurality of lower substrate processing modules are connected to the same exhaust system.

In one exemplary embodiment, at least one upper magnetic levitation type vacuum transport unit and at least one lower magnetic levitation type vacuum transport unit are disposed up and down in the vertical direction, and communicate with each other via an opening.

In one exemplary embodiment, the substrate processing system further includes a lifting/lowering transport robot configured to lift and lower between the at least one upper magnetic levitation type vacuum transport unit and the at least one lower magnetic levitation type vacuum transport unit via the opening to transport at least one substrate.

In one exemplary embodiment, the lifting/lowering transport robot includes a stage on which at least one substrate is placed, and a top portion that is disposed above the stage in the vertical direction and has a shape corresponding to the opening, and the lifting/lowering transport robot is configured to lift and lower in the vertical direction between an upper transport position at which the stage is disposed above the opening in the vertical direction, a standby position at which the top portion is disposed in the opening, and a lower transport position at which the top portion is disposed below the opening in the vertical direction.

In one exemplary embodiment, the at least one upper magnetic levitation type vacuum transport unit includes an upper horizontal plane motor extending in the horizontal direction, and the substrate processing system further includes an upper horizontal transport robot, and the upper horizontal transport robot is configured to move in the horizontal direction while being magnetically levitated on the upper horizontal plane motor to transport at least one substrate between the upper horizontal transport robot and the stage of the lifting/lowering transport robot at the upper transport position.

In one exemplary embodiment, the top portion of the lifting/lowering transport robot is configured to function as a part of the upper horizontal plane motor in a case where the lifting/lowering transport robot is at the standby position.

In one exemplary embodiment, the at least one lower magnetic levitation type vacuum transport unit includes a lower horizontal plane motor extending in the horizontal direction, and the substrate processing system further includes a lower horizontal transport robot, and the lower horizontal transport robot is configured to move in the horizontal direction while being magnetically levitated on the lower horizontal plane motor to transport at least one substrate between the lower horizontal transport robot and the stage of the lifting/lowering transport robot at the lower transport position.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Configuration Example of Substrate Processing System

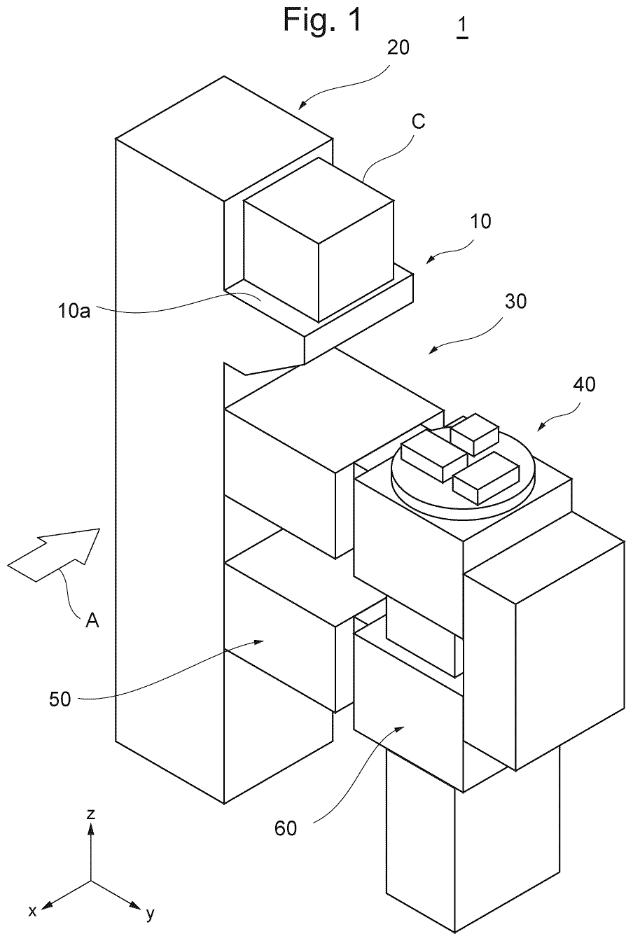

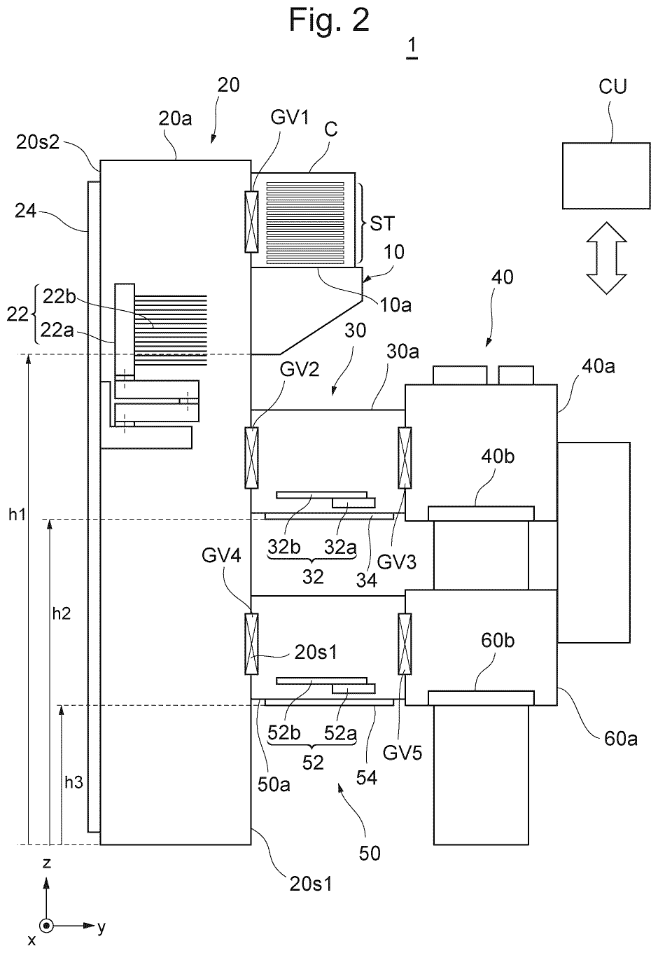

FIGS. 1 and 2 are diagrams for describing an example of a substrate processing system 1 according to an embodiment. FIG. 1 is a schematic perspective view of the substrate processing system 1. FIG. 2 is a schematic front view of the substrate processing system 1 (a view in the direction of an arrow A in FIG. 1). In FIG. 2, internal configuration elements of some apparatus are illustrated to be transmitted for convenience.

As illustrated in FIGS. 1 and 2, the substrate processing system 1 includes a load port (LP) 10, a load lock module (LLM) 20, an upper vacuum transport unit 30, an upper substrate processing module 40, a lower vacuum transport unit 50, and a lower substrate processing module 60. The upper vacuum transport unit 30 and the lower vacuum transport unit 50 are also referred to as an upper vacuum transfer module (VTM) and a lower vacuum transfer module, respectively. The upper substrate processing module 40 and the lower substrate processing module 60 are also referred to as an upper process module (PM) and a lower process module, respectively.

The substrate processing system 1 is controlled by a controller CU (see FIG. 2). The controller CU has a memory, a processor, and an input/output interface. Data such as a recipe, a program, or the like is stored in the memory. The memory is, for example, a random access memory (RAM), a read only memory (ROM), a hard disk drive (HDD), a solid state drive (SSD), or the like. The processor controls each unit of the substrate processing system 1 via the input/output interface by executing a program read out from the memory based on the data such as the recipe stored in the memory. The processor is a central processing unit (CPU), a digital signal processor (DSP), or the like.

A load port 10 includes a placement surface 10a. A container C is placed on the placement surface 10a. The container C may be configured such that a stack ST of a plurality of (for example, 25) substrates Wis accommodated. The container C may be, for example, a front-opening unified pod (FOUP). The container C is transported, for example, by a container transport mechanism such as an overhead hoist transport (OHT) and is placed on the load port 10. The container C is an example of a “substrate accommodation container” in the present disclosure. In an embodiment, a plurality of load ports 10 may be provided for one load lock module 20.

The load lock module 20 includes an internal pressure variable chamber 20a. The internal pressure variable chamber 20a is configured to switchable an interior between a vacuum and atmospheric pressure. The internal pressure variable chamber 20a has, for example, a housing having a substantially rectangular parallelepiped shape. The internal pressure variable chamber 20a may include an exhaust apparatus and a gas supply apparatus. For example, the controller CU controls the exhaust apparatus to exhaust air in the internal pressure variable chamber 20a, and switches the interior from the atmospheric atmosphere to the vacuum atmosphere. In addition, for example, the controller CU controls the gas supply apparatus to supply, for example, clean air into the internal pressure variable chamber 20a, and switches the interior from the vacuum atmosphere to the atmospheric atmosphere.

The internal pressure variable chamber 20a is connected to the container C on the load port 10 via a gate valve GV1. The gate valve GV1 is provided on any one side surface of the housing of the internal pressure variable chamber 20a. In the example illustrated in FIG. 2, the gate valve GV1 is provided on a side surface 20s1 of the housing of the internal pressure variable chamber 20a.

The internal pressure variable chamber 20a is connected to the upper vacuum transport unit 30 via a gate valve GV2. The internal pressure variable chamber 20a is connected to the lower vacuum transport unit 50 via a gate valve GV4. In the example illustrated in FIG. 2, the gate valve GV2 and the gate valve GV4 are provided on the same side surface 20s1 as the gate valve GV1. The gate valve GV2 is provided below the gate valve GV1 in a vertical direction (z direction). In addition, the gate valve GV4 is provided below the gate valve GV2 in the vertical direction (z direction). In the example illustrated in FIG. 2, the load port 10, the upper vacuum transport unit 30, and the lower vacuum transport unit 50 are disposed on the same side (side surface 20s1 side) with respect to the load lock module 20. In an embodiment, the upper vacuum transport unit 30 and the lower vacuum transport unit 50 are disposed on the same side (side surface 20s1 side) with respect to the load lock module 20, and the load port 10 is disposed on a side surface 20s2 opposite to the side surface 20s1.

A bottom surface of the load port 10 is disposed at a first height (h1) from a ground surface of the substrate processing system 1. A bottom surface of the upper vacuum transport unit 30 is disposed at a second height (h2) from a ground surface of the substrate processing system 1. A bottom surface of the lower vacuum transport unit 50 is disposed at a third height (h3) from the ground surface of the substrate processing system 1. The third height (h3) is lower than the second height (h2).

In an embodiment, the first height (h1) is different from the second height (h2) and the third height (h3). In the example illustrated in FIG. 2, the first height (h1) is higher than the second height (h2) and the third height (h3) (h1>h2>h3). In an embodiment, the first height (h1) is lower than the second height (h2) and higher than the third height (h3) (h2>h1>h3). In an embodiment, the first height (h1) is lower than the second height (h2) and the third height (h3) (h2>h3>h1). In an embodiment, the first height (h1) is equal to the second height (h2) and is higher than the third height (h3) (h1=h2>h3). In an embodiment, the first height (h1) is lower than the second height (h2) and is equal to the third height (h3) (h2>h1=h3).

A vertical transport robot 22 is disposed in the interior of the internal pressure variable chamber 20a. The vertical transport robot 22 includes an arm 22a. The arm 22a is configured to be capable of revolving, expanding and contracting, and lifting and lowering. The arm 22a has a plurality of end effectors 22b. Each end effector 22b is configured to be able to place each substrate W of the stack ST.

The vertical transport robot 22 is configured to move up and down in the vertical direction while being magnetically levitated on a vertical plane motor 24. The vertical plane motor 24 is disposed to extend in the vertical direction of the load lock module 20. The vertical plane motor 24 may be provided, for example, on the side surface 20s2 opposite to the side surface 20s1. The vertical plane motor 24 is configured by arranging a plurality of coils. Each coil generates a magnetic field by supplying a current. The controller CU individually controls a current value with which each coil is energized, thereby controlling the up-down movement of the vertical transport robot 22.

The vertical transport robot 22 transports the substrate W based on an operation instruction output by the controller CU. For example, the vertical transport robot 22 transports at least one substrate W between the load lock module 20 and the container C on the load port 10 in an atmospheric environment. In addition, for example, the vertical transport robot 22 holds at least one substrate W with the arm 22a and transports the substrate W up and down in the vertical direction in the load lock module 20. In an embodiment, the vertical transport robot 22 may collectively transport the stack ST of the plurality of substrates W using the plurality of end effectors 22b of the arm 22a. In an embodiment, a plurality of vertical transport robots 22 may be provided.

The upper vacuum transport unit 30 includes a vacuum chamber 30a. The vacuum chamber 30a may have a housing having a substantially rectangular parallelepiped shape. The vacuum chamber 30a is connected to the load lock module 20 via the above-described gate valve GV2. In addition, the vacuum chamber 30a is connected to the upper substrate processing module 40 via a gate valve GV3.

A magnetic levitation type upper horizontal transport robot 32 is disposed in the vacuum chamber 30a of the upper vacuum transport unit 30. In an embodiment, the upper horizontal transport robot 32 includes an arm 32a. The arm 32a is configured to be capable of revolving, expanding and contracting, and lifting and lowering. The arm 32a includes one or a plurality of end effectors 32b. The end effector 32b is configured to be able to place one substrate W.

The upper horizontal transport robot 32 is configured to move in a horizontal direction (xy direction) while being magnetically levitated on the upper horizontal plane motor 34. The upper horizontal plane motor 34 is disposed to extend in the horizontal direction on the bottom surface of the upper vacuum transport unit 30. The upper horizontal plane motor 34 is configured by arranging a plurality of coils. Each coil generates a magnetic field by supplying a current. The controller CU individually controls the current value with which each coil is energized, thereby controlling the movement of the upper horizontal transport robot 32 in the horizontal direction.

The upper horizontal transport robot 32 transports the substrate W based on an operation instruction output by the controller CU. For example, the upper horizontal transport robot 32 transports at least one substrate W between the load lock module 20 and the upper vacuum transport unit 30 in the vacuum environment. In addition, for example, the upper horizontal transport robot 32 transports the substrate W between the upper vacuum transport unit 30 and the upper substrate processing module 40 in the vacuum environment. In an embodiment, a plurality of upper horizontal transport robots 32 may be provided. The upper vacuum transport unit 30 is an example of an “upper magnetic levitation type vacuum transport unit” in the present disclosure.

The upper substrate processing module 40 has a processing chamber 40a. The processing chamber 40a is configured to be depressurized to a predetermined vacuum atmosphere and to perform desired processing (etching processing, film forming processing, cleaning processing, ashing processing, and the like) on the substrate W inside thereof. The processing chamber 40a is disposed adjacent to the upper vacuum transport unit 30. The processing chamber 40a may have a stage 40b on which the substrate W is placed. The operation of each part for the processing in the processing chamber 40a may be controlled by the controller CU. For example, the controller CU forms plasma from the processing gas introduced into the processing chamber 40a and performs the etching processing on the substrate W on the stage 40b using the plasma. In an embodiment, the processing chamber 40a may include a plurality of stages 40b (for example, two or four). That is, the upper substrate processing module 40 may be configured to perform processing of a plurality of substrates W at the same time in the processing chamber 40a.

The lower vacuum transport unit 50 includes a vacuum chamber 50a. The vacuum chamber 50a has, for example, a housing having a substantially rectangular parallelepiped shape. The vacuum chamber 50a is connected to the load lock module 20 via the above-described gate valve GV4. In addition, the vacuum chamber 50a is connected to the lower substrate processing module 60 via a gate valve GV5.

A magnetic levitation type lower horizontal transport robot 52 is disposed in the vacuum chamber 50a of the lower vacuum transport unit 50. In an embodiment, the lower horizontal transport robot 52 includes an arm 52a. The arm 52a is configured to be capable of revolving, expanding and contracting, and lifting and lowering. The arm 52a includes one or a plurality of end effectors 52b. The end effector 52b is configured to be able to place one substrate W.

The lower horizontal transport robot 52 is configured to move in the horizontal direction (xy direction) while being magnetically levitated on the lower horizontal plane motor 54. The lower horizontal plane motor 54 is disposed to extend in the horizontal direction on the bottom surface of the lower vacuum transport unit 50. The lower horizontal plane motor 54 is configured by arranging a plurality of coils. Each coil generates a magnetic field by supplying a current. The controller CU individually controls the current value with which each coil is energized, thereby controlling the movement of the lower horizontal transport robot 52 in the horizontal direction.

The lower horizontal transport robot 52 transports the substrate W based on an operation instruction output by the controller CU. For example, the lower horizontal transport robot 52 transports at least one substrate W between the load lock module 20 and the lower vacuum transport unit 50 in the vacuum environment. In addition, for example, the lower horizontal transport robot 52 transports the substrate W between the lower vacuum transport unit 50 and the lower substrate processing module 60 in the vacuum environment. In an embodiment, a plurality of lower horizontal transport robots 52 may be provided. The lower vacuum transport unit 50 is an example of a “lower magnetic levitation type vacuum transport unit” in the present disclosure.

The lower substrate processing module 60 has a processing chamber 60a. The processing chamber 60a is configured to be depressurized to a predetermined vacuum atmosphere and to perform desired processing (etching processing, film forming processing, cleaning processing, ashing processing, and the like) on the substrate W inside thereof. The processing chamber 60a is disposed adjacent to the lower vacuum transport unit 50. The processing chamber 60a may have a stage 60b on which the substrate W is placed. The operation of each part for the processing in the processing chamber 60a may be controlled by the controller CU. For example, the controller CU forms plasma from the processing gas introduced into the processing chamber 60a and performs the etching processing on the substrate W on the stage 60b with the plasma. In an embodiment, the processing chamber 60a may include a plurality of (for example, two or four) stages 60b. That is, the lower substrate processing module 60 may be configured to perform the processing of a plurality of substrates W at the same time in the processing chamber 60a.

### Example of Transport Operation of Substrate Processing System 1

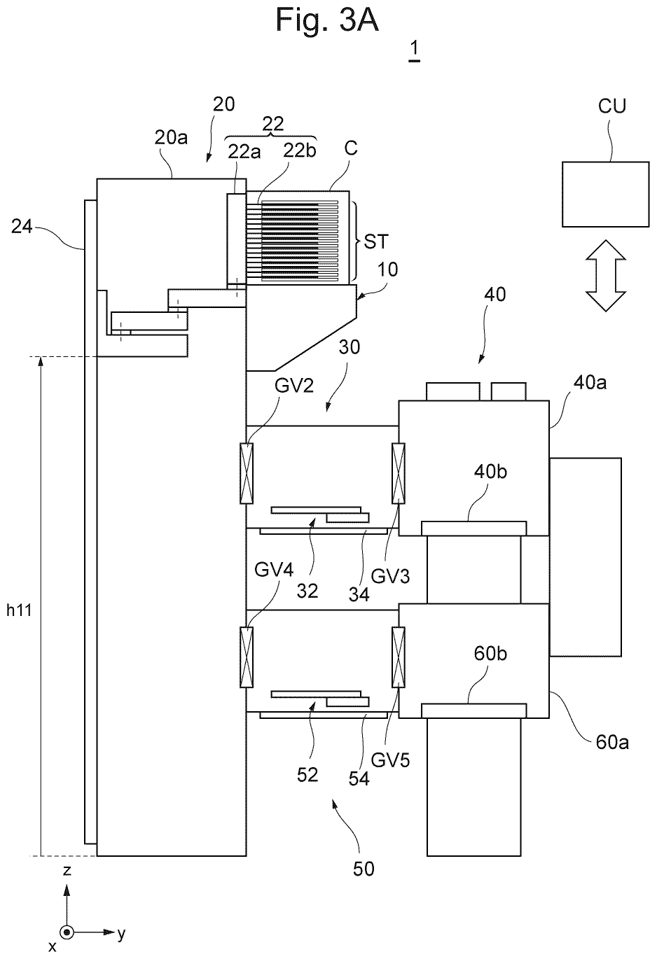

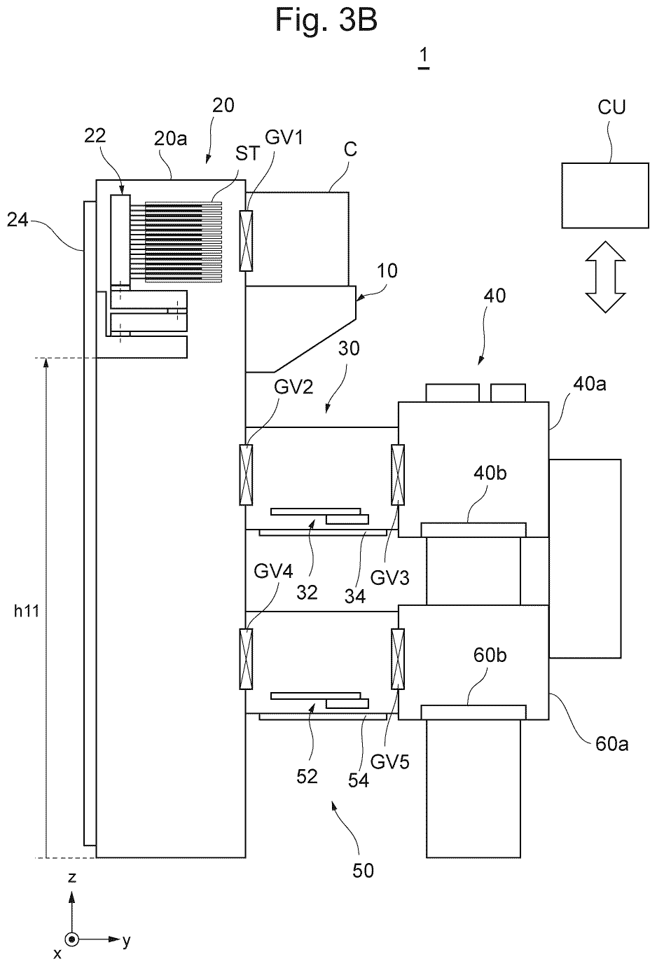

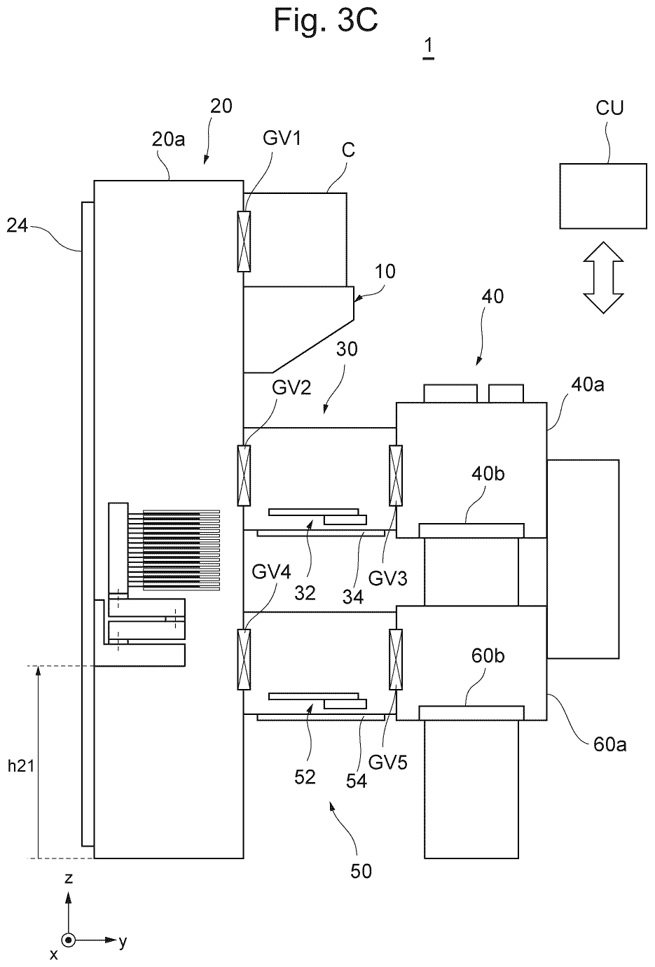

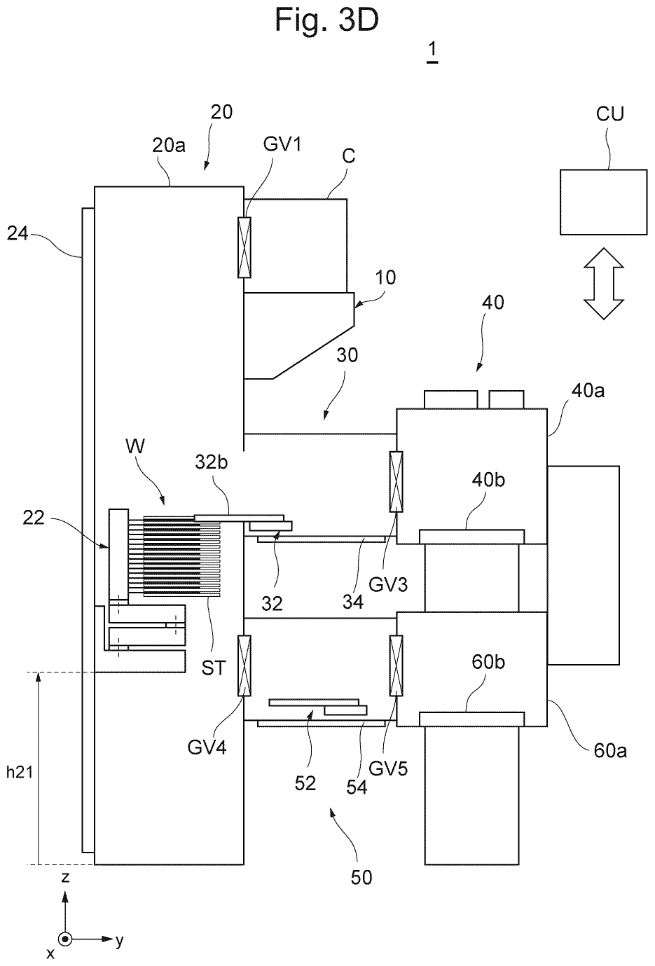

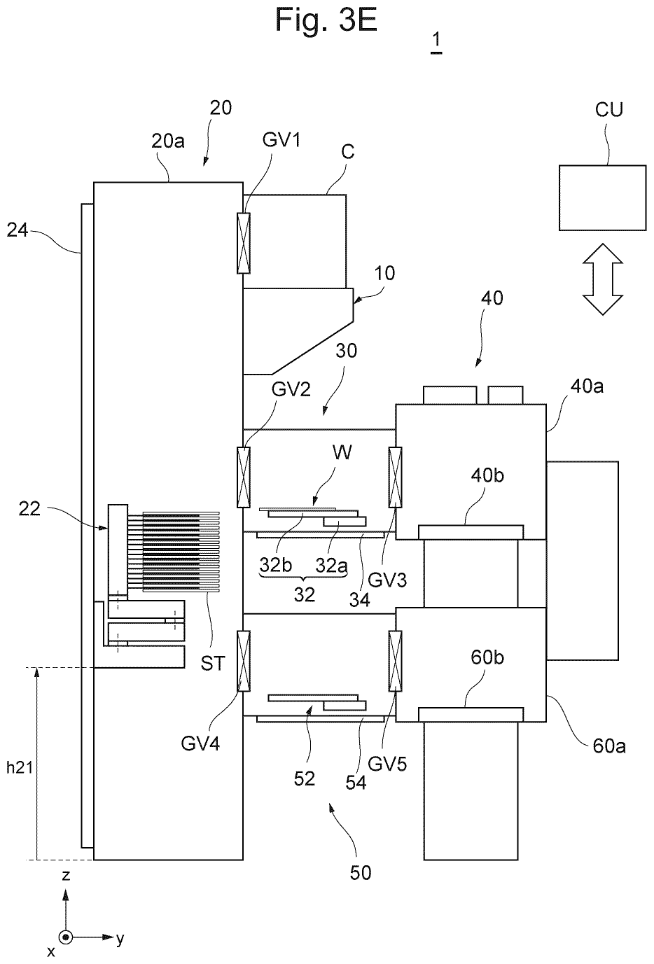

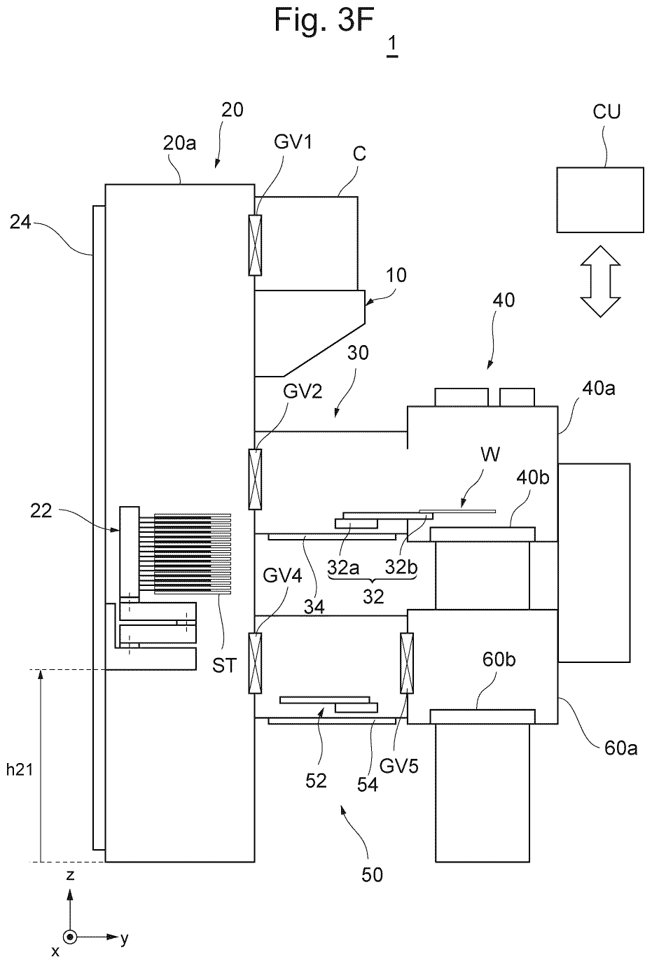

FIGS. 3A to 3F are diagrams for describing an example of a transport operation of the substrate processing system 1. Here, as an example of the transport operation, an operation of transporting the substrate W accommodated in the container C on the load port 10 to the processing chamber 40a of the upper substrate processing module 40 via the upper vacuum transport unit 30 will be described. This operation may be realized by controlling each part of the substrate processing system 1 by the controller CU. At a start time point of the operation, the gate valves GV1 to GV5 are closed, and the internal pressure variable chamber 20a of the load lock module 20 is in the atmospheric atmosphere. In addition, the vacuum chamber 30a of the upper vacuum transport unit 30 and the processing chamber 40a of the upper substrate processing module 40 are in the vacuum atmosphere. In addition, the vacuum chamber 50a of the lower vacuum transport unit 50 and the processing chamber 60a of the lower substrate processing module 60 are in the vacuum atmosphere.

First, as illustrated in FIG. 3A, the vertical transport robot 22 is lifted to a first transport height (h11) corresponding to the position of the load port 10. Then, the gate valve GV1 and a lid body of the container C are opened, and the arm 22a of the vertical transport robot 22 is inserted into the container C. Then, each of the substrates W of the stack ST in the container C is placed on each of the plurality of end effectors 22b.

Next, as illustrated in FIG. 3B, the arm 22a of the vertical transport robot 22 is returned to the internal pressure variable chamber 20a of the load lock module 20 in a state in which the stack ST is held, and the gate valve GV1 is closed. As a result, all the substrates W (stack ST) in the container C are collectively transported into the internal pressure variable chamber 20a of the load lock module 20.

Next, as illustrated in FIG. 3C, the vertical transport robot 22 is lowered in the vertical direction to a second transport height (h21) corresponding to the position of the upper vacuum transport unit 30 in a state in which the stack ST is held. At a timing at which the vertical transport robot 22 is lowered, air in the internal pressure variable chamber 20a may be discharged by the exhaust apparatus to switch the internal environment of the internal pressure variable chamber 20a from the atmospheric atmosphere to the vacuum atmosphere. The switching from the atmospheric atmosphere to the vacuum atmosphere may be executed at a timing before or after the lowering of the vertical transport robot 22.

Next, as illustrated in FIG. 3D, the gate valve GV2 is opened. The upper horizontal transport robot 32 moves horizontally near the gate valve GV2, and the end effector 32b is inserted into the internal pressure variable chamber 20a. Then, one substrate W in the stack ST is placed on the end effector 32b.

Next, as illustrated in FIG. 3E, the end effector 32b of the upper horizontal transport robot 32 is returned to the vacuum chamber 30a of the upper vacuum transport unit 30 in a state in which the substrate W is held, and the gate valve GV2 is closed. As a result, one substrate W in the stack ST is transported into the vacuum chamber 30a.

Next, as illustrated in FIG. 3F, the gate valve GV3 is opened, and the upper horizontal transport robot 32 moves horizontally near the gate valve GV3. Then, the end effector 32b holding the substrate W is inserted into the processing chamber 40a of the upper substrate processing module 40. As a result, the substrate W is disposed on the stage 40b of the processing chamber 40a. The substrate W may be placed, for example, on a plurality of pins configured to be movable up and down in the vertical direction from the stage 40b.

As described above, the substrate W accommodated in the container C placed on the load port 10 is transported to the processing chamber 40a of the upper substrate processing module 40. The substrate W processed in the processing chamber 40a of the upper substrate processing module 40 may be transported to the container C on the load port 10 by a procedure opposite to the above-described procedure.

The transport in and out of the substrate W between the container C on the load port 10 and the lower substrate processing module 60 may be performed in the same manner as described above. In this case, the vertical transport robot 22 is lowered in the vertical direction to a third transport height corresponding to the position of the lower vacuum transport unit 50 in a state in which the stack ST is held. A plurality of vertical transport robots 22 may be provided. For example, while a certain vertical transport robot 22 transports the substrate W to the upper vacuum transport unit 30, another vertical transport robot 22 may transport the substrate W to the lower vacuum transport unit 50.

The substrate processing system 1 may execute the transport of the substrate W via the upper substrate processing module 40 and the transport of the substrate W via the lower substrate processing module 60 in parallel. Therefore, the transport efficiency of the substrate may be improved. In addition, the substrate processing system 1 may execute the processing of the substrate W in the upper substrate processing module 40 and the processing of the substrate W in the lower substrate processing module 60 in parallel. Since the substrate processing system 1 may transport and process the substrate W in two up and lower stages, productivity may be improved while suppressing an installation area of the substrate processing system 1. That is, the productivity per unit area may be improved.

### Example of Apparatus Layout of Substrate Processing System 1

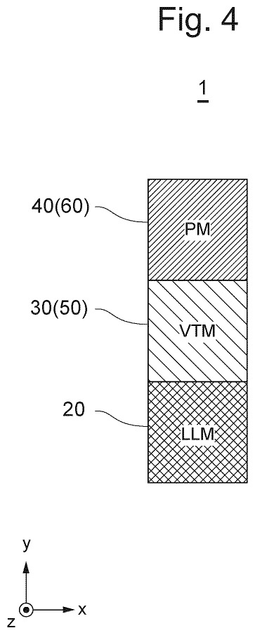

FIG. 4 is a diagram for describing an apparatus layout of the substrate processing system 1. FIG. 4 illustrates the apparatus layout in a case where the substrate processing system 1 is viewed in plan view (xy plane). In FIG. 4, “LLM” indicates the “load lock module 20”. “VTM” indicates the “upper vacuum transport unit 30” and the “lower vacuum transport unit 50” disposed below the upper vacuum transport unit 30 in the vertical direction. “PM” indicates the “upper substrate processing module 40” and the “lower substrate processing module 60” disposed below the upper substrate processing module 40 in the vertical direction.

In the example illustrated in FIG. 4, each block of the LLM, the upper VTM, and the upper PM are disposed side by side one by one in a y direction. In addition, each block of the LLM, the lower VTM, and the lower PM are disposed side by side one by one in the y direction. Although not illustrated in FIG. 4, each block may be connected to be openable and closable via the gate valves GV2 to GV5 (hereinafter, also collectively referred to as “gate valves”) as illustrated in FIG. 2.

In an embodiment, the substrate processing system 1 may be configured such that each block of the LLM, the upper VTM, and the upper PM is connected in one or more in a first direction in the horizontal direction (xy direction). In addition, the substrate processing system 1 may be configured such that each block of the LLM, the lower VTM, and the lower PM is connected in one or more in a second direction in the horizontal direction (xy direction). In an embodiment, the first direction and the second direction are the same. In an embodiment, the first direction and the second direction are different directions, for example, directions orthogonal to each other.

The position of the gate valve of each block may be appropriately changed according to the apparatus layout. In a case where the substrate processing system 1 includes a plurality of VTM, each VTM may be connected to each other in the horizontal direction (xy direction) via the opening portion. In an embodiment, the upper horizontal transport robot 32 may move in the horizontal direction across a plurality of upper VTM via the opening portion while being magnetically levitated on the upper horizontal plane motor 34 of each of the plurality of upper VTM. In an embodiment, the lower horizontal transport robot 52 may move in the horizontal direction across a plurality of lower VTM via the opening portion while being magnetically levitated on the lower horizontal plane motor 54 of each of the plurality of lower VTM.

According to the above, in the substrate processing system 1, the apparatus layout of the LLM, the VTM, and the PM may be freely changed. A plurality of vertical transport robots 22, upper horizontal transport robots 32, and/or lower horizontal transport robots 52 may be provided in accordance with the apparatus layout. Accordingly, it is possible to suppress the transport of the substrate in the LLM or the VTM from being rate-limiting and the transport efficiency from being decreased.

### Modification Examples

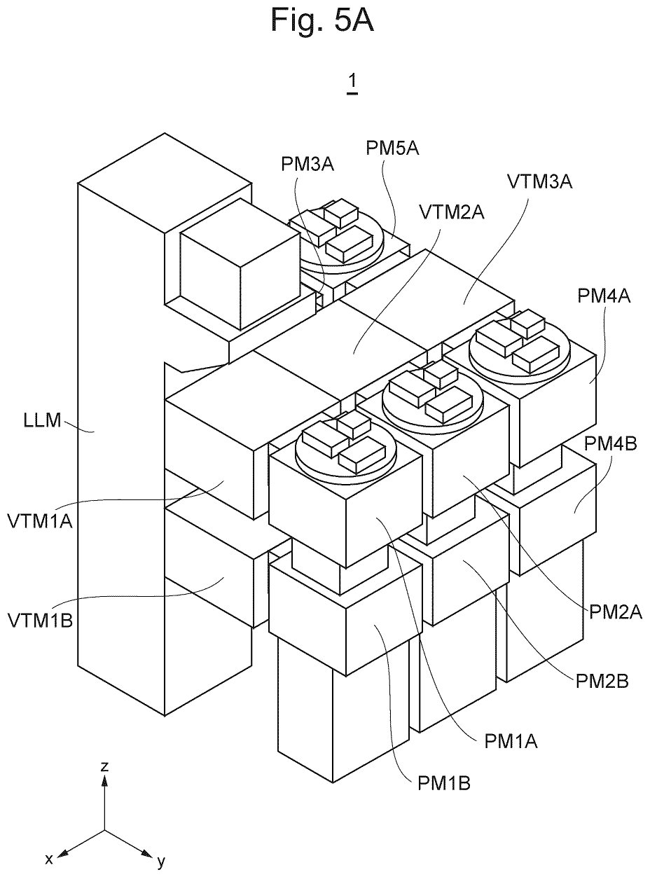

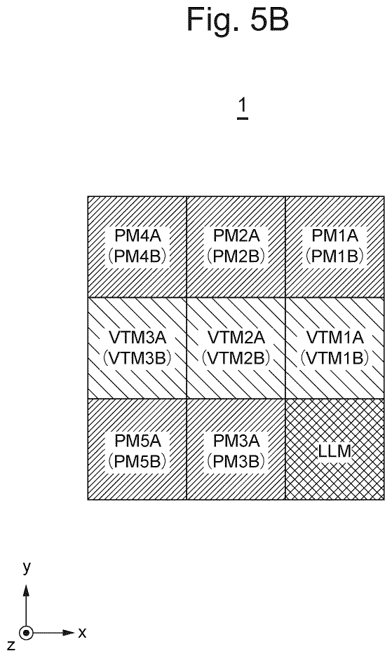

FIGS. 5A and 5B are diagrams for describing another example of the apparatus layout of the substrate processing system 1. In this example, in the substrate processing system 1, three VTM1A to VTM3A (corresponding to the “upper vacuum transport unit 30”, respectively) are connected to an upper stage of one LLM (corresponding to the load lock module 20). In addition, three VTM1B to VTM3B (corresponding to the “lower vacuum transport unit 50”, respectively) are connected to a lower stage of the LLM. In this example, the three upper VTM1A to VTM3A are connected along the x direction (first direction). Similarly, the lower VTM1B to VTM3B are connected along the x direction (first direction).

The VTM 1A corresponds to the PM 1A (corresponding to the “upper substrate processing module 40”) on one side surface (first side surface) extending along the x direction, the same applies to the PM2A and the like below.) is connected thereto and is connected to the LLM on the other side surface (second side surface) opposite to the one side surface. The VTM2A is connected to the PM2A on one side surface (first side surface) extending along the x direction and is connected to the PM3A on the other side surface (second side surface). The VTM 3A is connected to the PM4A on one side surface (first side surface) extending along the x direction and is connected to the PM5A on the other side surface (second side surface).

The VTM1B is connected to the PM1B on one side surface (first side surface) extending along the x direction, and is connected to the LLM on the other side surface (second side surface) opposite to the one side surface. The VTM2B is connected to the PM2B on one side surface (first side surface) extending along the x direction and is connected to the PM3B on the other side surface (second side surface). The VTM3B is connected to the PM4B on one side surface (first side surface) extending along the x direction and is connected to the PM5B on the other side surface (second side surface).

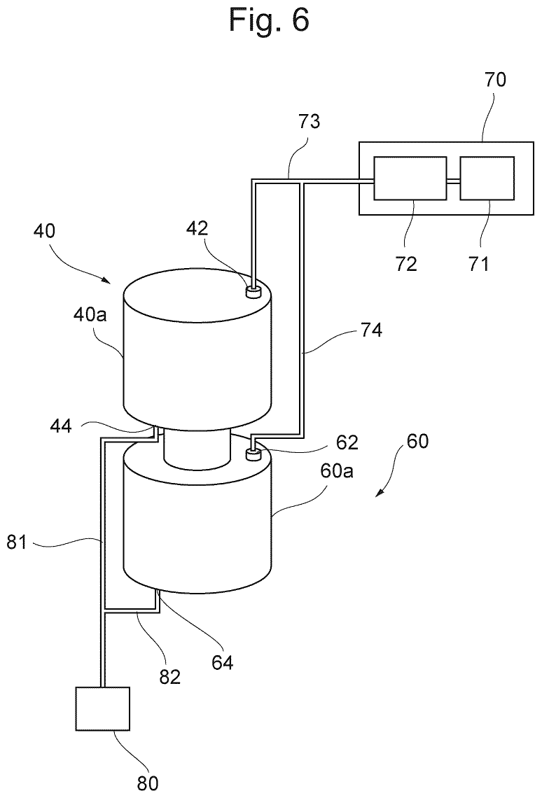

FIG. 6 is a diagram for describing another example of the upper substrate processing module 40 and the lower substrate processing module 60. In an embodiment, the upper substrate processing module 40 and the lower substrate processing module 60 are connected to a common gas supply portion 70. The gas supply portion 70 may include at least one gas source 71 and at least one flow rate controller 72.

The gas supply portion 70 is configured to supply at least one processing gas to the upper substrate processing module 40. The processing gas supplied from the gas source 71 is introduced into the inside of the processing chamber 40a of the upper substrate processing module 40 from a gas supply port 42 via the flow rate controller 72 and an upper supply passage 73.

The gas supply portion 70 is configured to supply at least one processing gas to the lower substrate processing module 60. The processing gas supplied from the gas source 71 is introduced into the inside of the processing chamber 60a of the upper substrate processing module 60 from the gas supply port 62 via the flow rate controller 72 and the upper supply passage 73.

In an embodiment, the gas supply portion 70 may be connected to a plurality of upper substrate processing modules 40 and/or a plurality of lower substrate processing modules 60.

In an embodiment, the upper substrate processing module 40 and the lower substrate processing module 60 are connected to a common exhaust system 80. The exhaust system 80 is connected to the gas discharge port 44 of the upper substrate processing module 40 via an upper discharge passage 81. The gas discharge port 44 may be provided, for example, at the bottom portion of the processing chamber 40a. The exhaust system 80 is connected to the gas discharge port 64 of the lower substrate processing module 60 via a lower discharge passage 82. The gas discharge port 64 may be provided, for example, at a bottom portion of the processing chamber 60a.

The exhaust system 80 includes a pressure adjusting valve, and the pressure adjusting valve may adjust the internal pressures of the processing chamber 40a and the processing chamber 60a. The exhaust system 80 may include a vacuum pump. The vacuum pump may include a turbomolecular pump, a dry pump, or a combination thereof.

In an embodiment, the exhaust system 80 may be connected to a plurality of upper substrate processing modules 40 and/or a plurality of lower substrate processing modules 60.

In the example illustrated in FIG. 6, the upper substrate processing module 40 and the lower substrate processing module 60 are connected to the same gas supply portion 70 and the same exhaust system 80. The controller CU may control the flow rate of the processing gas supplied to the processing chamber 40a and the processing chamber 60a, and the pressure of the interior at the same time. As a result, the substrate W may be processed in parallel in the upper substrate processing module 40 and the lower substrate processing module 60 using the same recipe (condition).

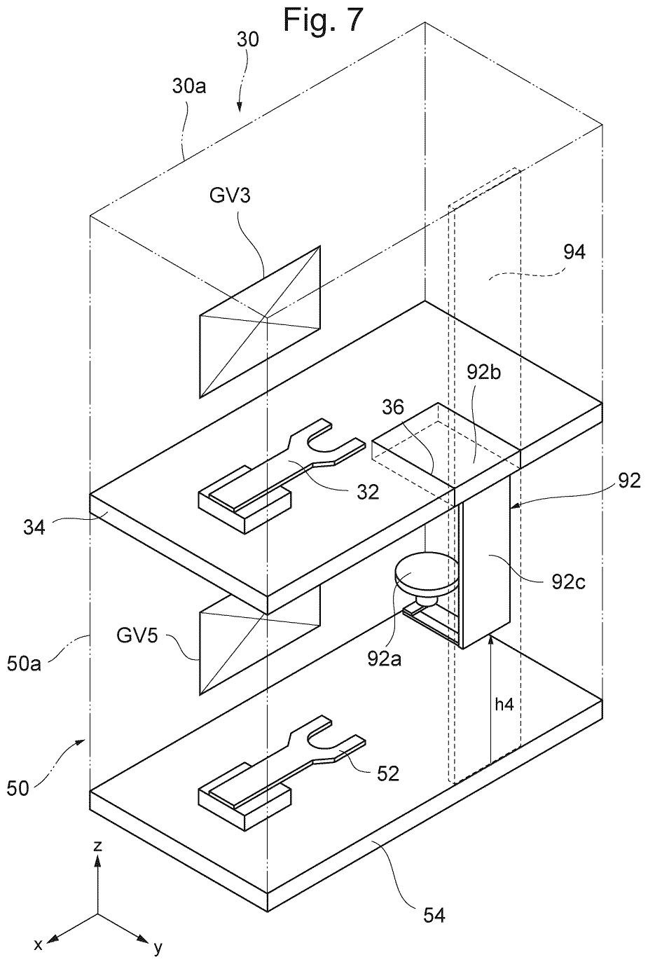

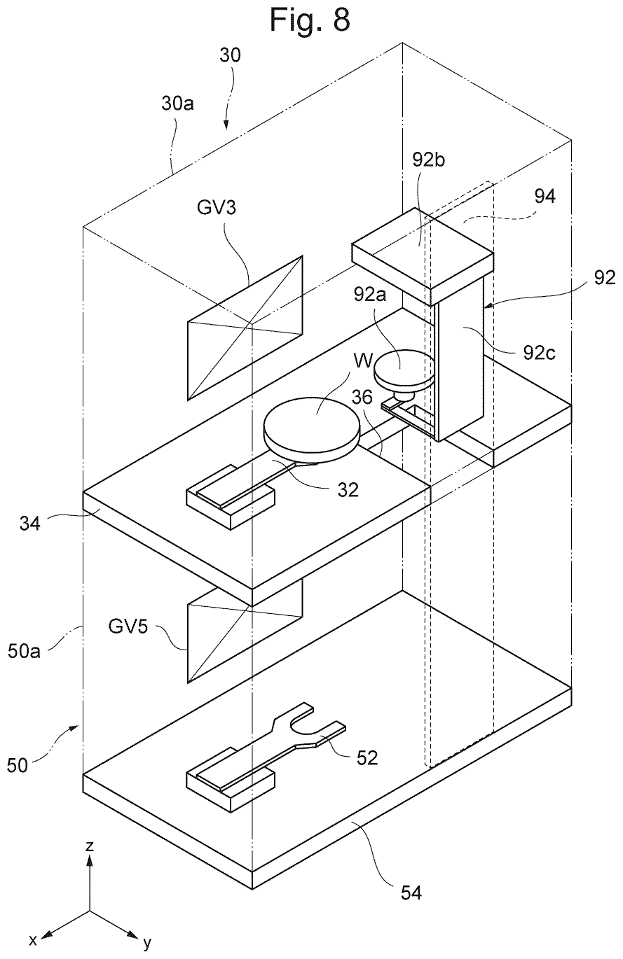

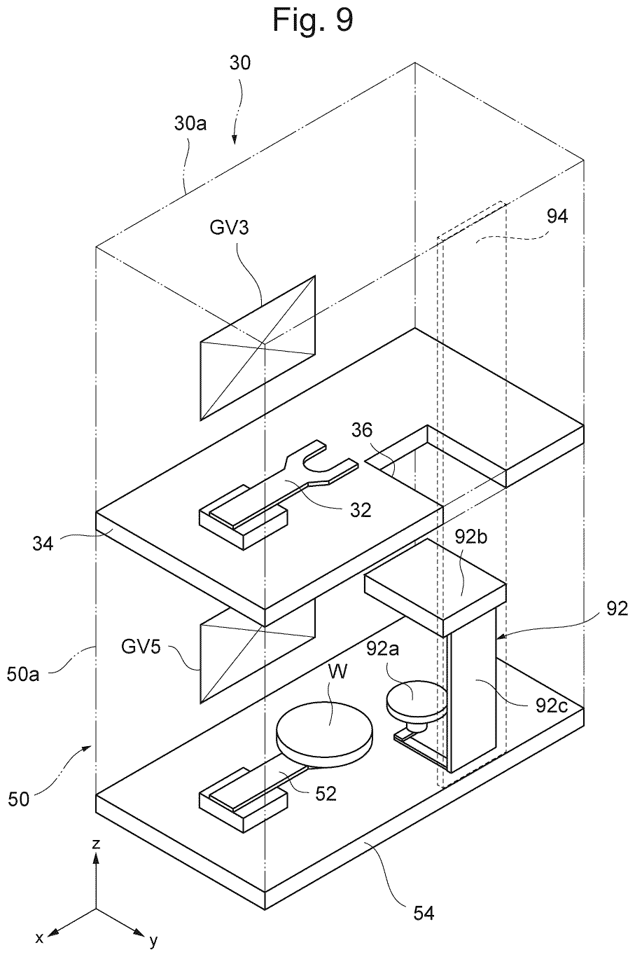

FIGS. 7 to 9 are diagrams for describing other examples of the upper vacuum transport unit 30 and the lower vacuum transport unit 50. FIG. 7 is a diagram illustrating a state in which a lifting/lowering transport robot 92, which will be described later, is at a standby position. FIG. 8 is a diagram illustrating a state in which the lifting/lowering transport robot 92 is at an upper transport position. FIG. 9 is a diagram illustrating a state in which the lifting/lowering transport robot 92 is at a lower transport position.

In an embodiment, the upper vacuum transport unit 30 and the lower vacuum transport unit 50 are connected to each other up and down in the vertical direction. In the examples illustrated in FIGS. 7 to 9, the upper vacuum transport unit 30 and the lower vacuum transport unit 50 may communicate with each other via an opening 36. The opening 36 is a through-hole that penetrates a part of the bottom surface of the vacuum chamber 30a of the upper vacuum transport unit 30, a part of the upper horizontal plane motor 34 corresponding to the bottom surface, and an upper surface of the vacuum chamber 50a of the lower vacuum transport unit 50.

The opening 36 provides a passage for the lifting/lowering transport robot 92. The lifting/lowering transport robot 92 is configured to move up and down in the vertical direction through the opening 36 between the vacuum chamber 30a of the upper vacuum transport unit 30 and the vacuum chamber 50a of the lower vacuum transport unit 50. The lifting/lowering transport robot 92 is configured to be capable of lifting and lowering in the vertical direction between each of a standby position (FIG. 7), an upper transport position (FIG. 8), and a lower transport position (FIG. 9).

In an embodiment, the lifting/lowering transport robot 92 is configured to move up and down in the vertical direction while being magnetically levitated on the vertical plane motor 94. The vertical plane motor 94 is disposed, for example, on the same side surface of the upper vacuum transport unit 30 and the lower vacuum transport unit 50, by being extended in the vertical direction. The vertical plane motor 94 is configured by arranging a plurality of coils. Each coil generates a magnetic field by supplying a current. The controller CU individually controls the current value with which each coil is energized, thereby controlling the movement of the lifting/lowering transport robot 92 up and down in the vertical direction.

In an embodiment, the lifting/lowering transport robot 92 includes a stage 92a and a top portion 92b. The stage 92a is configured to be able to place at least one substrate W. The top portion 92b is provided above the stage 92a in the vertical direction. The stage 92a and the top portion 92b may be connected to each other via a connecting portion 92c extending in the vertical direction.

The top portion 92b includes a shape corresponding to the opening 36 in plan view (xy plane). The top portion 92b may have a shape similar to the shape of the opening 36 in plan view and may have a width and a length (in the x direction and the y direction) slightly smaller than those of the opening 36.

As illustrated in FIG. 7, the lifting/lowering transport robot 92 is disposed and moved to the standby position in a state in which the substrate W is not transported (FIG. 7). At the standby position, the lifting/lowering transport robot 92 is disposed at a position that does not hinder movement of each of the upper horizontal transport robot 32 and the lower horizontal transport robot 52 in the horizontal direction. Specifically, the top portion 92b of the lifting/lowering transport robot 92 is disposed in the opening 36. The top portion 92b closes the opening 36 and configures a part of the bottom surface of the vacuum chamber 30a of the upper vacuum transport unit 30. In addition, the stage 92a of the lifting/lowering transport robot 92 is disposed at a height (h4) separated from the bottom surface of the vacuum chamber 50a. This height (h4) can be appropriately set in accordance with a size of the lower horizontal transport robot 52 and an operating range in the vertical direction.

The top portion 92b may be configured to function as a part of the upper horizontal plane motor 34 in a state of being disposed in the opening 36. For example, the top portion 92b may be configured such that a plurality of coils are arranged inside thereof and a magnetic field is generated on the top portion 92b in accordance with a supplied current. The controller CU may individually control current values for energizing each coil of the upper horizontal plane motor 34 and the top portion 92b, thereby controlling the movement of the upper horizontal transport robot 32 in the horizontal direction.

As illustrated in FIG. 8, in a case of transporting the substrate W between the lifting/lowering transport robot 92 and the upper horizontal transport robot 32, the lifting/lowering transport robot 92 is disposed and moved to the upper transport position. At the upper transport position, the stage 92a is disposed above the opening 36 in the vertical direction. For example, the controller CU lifts and lowers the lifting/lowering transport robot 92 such that the stage 92a is at the same height as the substrate W on the end effector 32b of the upper horizontal transport robot 32. The controller CU may control the drive of the arm 32a and the end effector 32b of the upper horizontal transport robot 32 to transport at least one substrate W between the upper horizontal transport robot 32 and the stage 92a.

As illustrated in FIG. 9, the lifting/lowering transport robot 92 is disposed and moved to the lower transport position in a case of transporting the substrate W between the lifting/lowering transport robot 92 and the lower horizontal transport robot 52. At the lower transport position, the stage 92a and the top portion 92b are disposed below the opening 36 in the vertical direction. For example, the controller CU lifts and lowers the lifting/lowering transport robot 92 such that the stage 92a is at the same height as the substrate W on the end effector 52b of the lower horizontal transport robot 52. The controller CU may control the drive of the arm 52a and the end effector 52b of the lower horizontal transport robot 52 to transport at least one substrate W between the lower horizontal transport robot 52 and the stage 92a.

According to the aspect illustrated in FIGS. 7 to 9, the substrate W may be transported between the upper vacuum transport unit 30 and the lower vacuum transport unit 50. Accordingly, the number of transport paths of the substrate W may be increased, and thus the transport efficiency of the substrate may be improved.

According to an embodiment, it is possible to provide a technique for improving the transport efficiency of the substrate.

The embodiments of the present disclosure further include the following aspects.

### Addendum 1

A substrate processing system including:
a load port disposed at a first height;
a plurality of upper magnetic levitation type vacuum transport units disposed at a second height, the plurality of upper magnetic levitation type vacuum transport units being connected in a horizontal direction along a first direction;
a plurality of upper substrate processing modules, each of the upper substrate processing modules being connected to any of the plurality of upper magnetic levitation type vacuum transport units;
a plurality of lower magnetic levitation type vacuum transport units disposed at a third height lower than the second height, the plurality of lower magnetic levitation type vacuum transport units being connected in the horizontal direction along the first direction;
a plurality of lower substrate processing modules, each of the lower substrate processing modules being connected to any of the plurality of lower magnetic levitation type vacuum transport units; and
a load lock module configured to switch an internal environment between an atmospheric environment and a vacuum environment, the load lock module being configured to
transport at least one substrate between the load lock module and a substrate accommodation container on the load port under the atmospheric environment,
transport at least one substrate in a vertical direction,
transport at least one substrate between the load lock module and any of the plurality of upper magnetic levitation type vacuum transport units under the vacuum environment, and
transport at least one substrate between the load lock module and any of the plurality of lower magnetic levitation type vacuum transport units under the vacuum environment.

### Addendum 2

The substrate processing system according to Addendum 1,
in which the first height is higher than the second height.

### Addendum 3

The substrate processing system according to Addendum 1 or 2,
in which the load lock module
is connected to any of the plurality of upper magnetic levitation type vacuum transport units on a first side surface, and
is connected to any of the plurality of lower magnetic levitation type vacuum transport units on the first side surface.

### Addendum 4

The substrate processing system according to Addendum 3,
in which the load lock module is connected to the load port on the first side surface.

### Addendum 5

The substrate processing system according to any one of Addenda 1 to 4, further including:
a vertical transport robot disposed in the load lock module,
in which the vertical transport robot is configured to transport a stack of a plurality of substrates between the load lock module and the substrate accommodation container on the load port, and to transport the stack of the plurality of substrates in the vertical direction.

### Addendum 6

The substrate processing system according to Addendum 5,
in which the load lock module includes a vertical plane motor extending in the vertical direction, and
the vertical transport robot is configured to move in the vertical direction while being magnetically levitated on the vertical plane motor to transport the stack of the plurality of substrates in the vertical direction.

### Addendum 7

The substrate processing system according to any one of Addenda 1 to 6,
in which each of the plurality of upper magnetic levitation type vacuum transport units includes an upper horizontal plane motor extending in the horizontal direction, and
the substrate processing system further includes an upper horizontal transport robot, and the upper horizontal transport robot is configured to move in the horizontal direction while being magnetically levitated on the upper horizontal plane motor to transport at least one substrate between the load lock module and the plurality of upper substrate processing modules.

### Addendum 8

The substrate processing system according to any one of Addenda 1 to 7,
in which each of the plurality of lower magnetic levitation type vacuum transport units includes a lower horizontal plane motor extending in the horizontal direction, and
the substrate processing system further includes a lower horizontal transport robot, and the lower horizontal transport robot is configured to move in the horizontal direction while being magnetically levitated on the lower horizontal plane motor to transport at least one substrate between the load lock module and the plurality of lower substrate processing modules.

### Addendum 9

The substrate processing system according to any one of Addenda 1 to 8,
in which each of the plurality of upper magnetic levitation type vacuum transport units includes an upper horizontal plane motor extending in the horizontal direction, and
the substrate processing system further includes a plurality of upper horizontal transport robots, and the plurality of upper horizontal transport robots are configured to move in the horizontal direction while being magnetically levitated on the upper horizontal plane motor to transport a plurality of substrates between the load lock module and the plurality of upper substrate processing modules at the same time.

### Addendum 10

The substrate processing system according to any one of Addenda 1 to 9,
in which each of the plurality of lower magnetic levitation type vacuum transport units includes a lower horizontal plane motor extending in the horizontal direction, and
the substrate processing system further includes a plurality of lower horizontal transport robots, and the plurality of lower horizontal transport robots are configured to move in the horizontal direction while being magnetically levitated on the lower horizontal plane motor to transport a plurality of substrates between the load lock module and the plurality of lower substrate processing modules at the same time.

### Addendum 11

The substrate processing system according to any one of Addenda 1 to 10,
in which at least one of the plurality of upper substrate processing modules and the plurality of lower substrate processing modules includes a chamber configured to process four substrates at the same time.

### Addendum 12

The substrate processing system according to any one of Addenda 1 to 11,
in which at least one of the plurality of upper substrate processing modules and the plurality of lower substrate processing modules includes a chamber configured to process two substrates at the same time.

### Addendum 13

The substrate processing system according to any one of Addenda 1 to 12,
in which at least one chamber of the plurality of upper substrate processing modules and at least one chamber of the plurality of lower substrate processing modules are connected to the same gas supply portion.

### Addendum 14

The substrate processing system according to any one of Addenda 1 to 13,
in which at least one chamber of the plurality of upper substrate processing modules and at least one chamber of the plurality of lower substrate processing modules are connected to the same exhaust system.

### Addendum 15

The substrate processing system according to any one of Addenda 1 to 14,
in which at least one upper magnetic levitation type vacuum transport unit and at least one lower magnetic levitation type vacuum transport unit are disposed up and down in the vertical direction, and communicate with each other via an opening.

### Addendum 16

The substrate processing system according to Addendum 15, further including:
a lifting/lowering transport robot configured to lift and lower between the at least one upper magnetic levitation type vacuum transport unit and the at least one lower magnetic levitation type vacuum transport unit via the opening portion to transport at least one substrate.

### Addendum 17

The substrate processing system according to Addendum 16,
in which the lifting/lowering transport robot includes a stage on which at least one substrate is placed, and a top portion that is disposed above the stage in the vertical direction and has a shape corresponding to the opening, and
the lifting/lowering transport robot is configured to lift and lower in the vertical direction between an upper transport position at which the stage is disposed above the opening in the vertical direction, a standby position at which the top portion is disposed in the opening, and a lower transport position at which the top portion is disposed below the opening in the vertical direction.

### Addendum 18

The substrate processing system according to Addendum 17,
in which the at least one upper magnetic levitation type vacuum transport unit includes an upper horizontal plane motor extending in the horizontal direction, and
the substrate processing system further includes an upper horizontal transport robot, and the upper horizontal transport robot is configured to move in the horizontal direction while being magnetically levitated on the upper horizontal plane motor to transport at least one substrate between the upper horizontal transport robot and the stage of the lifting/lowering transport robot at the upper transport position.

### Addendum 19

The substrate processing system according to Addendum 17 or 18,
in which the top portion of the lifting/lowering transport robot is configured to function as a part of the upper horizontal plane motor in a case where the lifting/lowering transport robot is at the standby position.

### Addendum 20

The substrate processing system according to any one of Addenda 17 to 19,
in which the at least one lower magnetic levitation type vacuum transport unit includes a lower horizontal plane motor extending in the horizontal direction, and
the substrate processing system further includes a lower horizontal transport robot, and the lower horizontal transport robot is configured to move in the horizontal direction while being magnetically levitated on the lower horizontal plane motor to transport at least one substrate between the lower horizontal transport robot and the stage of the lifting/lowering transport robot at the lower transport position.

Each of the above-described embodiments is described for the purpose of description, and is not intended to limit the scope of the present disclosure. Each of the above-described embodiments may be modified in various ways without departing from the scope and gist of the present disclosure. For example, some configuration elements in one embodiment can be added to another embodiment. In addition, some configuration elements in one embodiment are able to be replaced with corresponding configuration elements in another embodiment.

What is claimed is:

1. A substrate processing system comprising:
a load port disposed at a first height;
a plurality of upper magnetic levitation type vacuum transport units disposed at a second height, the plurality of upper magnetic levitation type vacuum transport units being connected in a horizontal direction along a first direction;
a plurality of upper substrate processing modules, each of the upper substrate processing modules being connected to any of the plurality of upper magnetic levitation type vacuum transport units;
a plurality of lower magnetic levitation type vacuum transport units disposed at a third height lower than the second height, the plurality of lower magnetic levitation type vacuum transport units being connected in the horizontal direction along the first direction;
a plurality of lower substrate processing modules, each of the lower substrate processing modules being connected to any of the plurality of lower magnetic levitation type vacuum transport units; and
a load lock module configured to switch an internal environment between an atmospheric environment and a vacuum environment, the load lock module being configured to
transport at least one substrate between the load lock module and a substrate accommodation container on the load port under the atmospheric environment,
transport at least one substrate in a vertical direction,
transport at least one substrate between the load lock module and any of the plurality of upper magnetic levitation type vacuum transport units under the vacuum environment, and
transport at least one substrate between the load lock module and any of the plurality of lower magnetic levitation type vacuum transport units under the vacuum environment.

2. The substrate processing system according to claim 1,
wherein the first height is higher than the second height.

3. The substrate processing system according to claim 2,
wherein the load lock module
is connected to any of the plurality of upper magnetic levitation type vacuum transport units on a first side surface, and
is connected to any of the plurality of lower magnetic levitation type vacuum transport units on the first side surface.

4. The substrate processing system according to claim 3,
wherein the load lock module is connected to the load port on the first side surface.

5. The substrate processing system according to claim 4, further comprising:
a vertical transport robot disposed in the load lock module,
wherein the vertical transport robot is configured to transport a stack of a plurality of substrates between the load lock module and the substrate accommodation container on the load port, and to transport the stack of the plurality of substrates in the vertical direction.

6. The substrate processing system according to claim 5,
wherein the load lock module includes a vertical plane motor extending in the vertical direction, and
the vertical transport robot is configured to move in the vertical direction while being magnetically levitated on the vertical plane motor to transport the stack of the plurality of substrates in the vertical direction.

7. The substrate processing system according to claim 5,
wherein each of the plurality of upper magnetic levitation type vacuum transport units includes an upper horizontal plane motor extending in the horizontal direction, and
the substrate processing system further comprises an upper horizontal transport robot, and the upper horizontal transport robot is configured to move in the horizontal direction while being magnetically levitated on the upper horizontal plane motor to transport at least one substrate between the load lock module and the plurality of upper substrate processing modules.

8. The substrate processing system according to claim 7,
wherein each of the plurality of lower magnetic levitation type vacuum transport units includes a lower horizontal plane motor extending in the horizontal direction, and
the substrate processing system further comprises a lower horizontal transport robot, and the lower horizontal transport robot is configured to move in the horizontal direction while being magnetically levitated on the lower horizontal plane motor to transport at least one substrate between the load lock module and the plurality of lower substrate processing modules.

9. The substrate processing system according to claim 5,
wherein each of the plurality of upper magnetic levitation type vacuum transport units includes an upper horizontal plane motor extending in the horizontal direction, and
the substrate processing system further comprises a plurality of upper horizontal transport robots, and the plurality of upper horizontal transport robots are configured to move in the horizontal direction while being magnetically levitated on the upper horizontal plane motor to transport the plurality of substrates between the load lock module and the plurality of upper substrate processing modules at the same time.

10. The substrate processing system according to claim 7,
wherein each of the plurality of lower magnetic levitation type vacuum transport units includes a lower horizontal plane motor extending in the horizontal direction, and
the substrate processing system further comprises a plurality of lower horizontal transport robots, and the plurality of lower horizontal transport robots are configured to move in the horizontal direction while being magnetically levitated on the lower horizontal plane motor to transport the plurality of substrates between the load lock module and the plurality of lower substrate processing modules at the same time.

11. The substrate processing system according to claim 1,
wherein at least one of the plurality of upper substrate processing modules and the plurality of lower substrate processing modules includes a chamber configured to process four substrates at the same time.

12. The substrate processing system according to claim 1,
wherein at least one of the plurality of upper substrate processing modules and the plurality of lower substrate processing modules includes a chamber configured to process two substrates at the same time.

13. The substrate processing system according to claim 1,
wherein at least one chamber of the plurality of upper substrate processing modules and at least one chamber of the plurality of lower substrate processing modules are connected to the same gas supply portion.

14. The substrate processing system according to claim 13,
wherein at least one chamber of the plurality of upper substrate processing modules and at least one chamber of the plurality of lower substrate processing modules are connected to the same exhaust system.

15. The substrate processing system according to claim 1,
wherein at least one upper magnetic levitation type vacuum transport unit and at least one lower magnetic levitation type vacuum transport unit are disposed up and down in the vertical direction, and communicate with each other via an opening.

16. The substrate processing system according to claim 15, further comprising:
a lifting/lowering transport robot configured to lift and lower between the at least one upper magnetic levitation type vacuum transport unit and the at least one lower magnetic levitation type vacuum transport unit via the opening to transport at least one substrate.

17. The substrate processing system according to claim 16,
wherein the lifting/lowering transport robot includes a stage on which at least one substrate is placed, and a top portion that is disposed above the stage in the vertical direction and has a shape corresponding to the opening, and
the lifting/lowering transport robot is configured to lift and lower in the vertical direction between an upper transport position at which the stage is disposed above the opening in the vertical direction, a standby position at which the top portion is disposed in the opening, and a lower transport position at which the top portion is disposed below the opening in the vertical direction.

18. The substrate processing system according to claim 17,
wherein the at least one upper magnetic levitation type vacuum transport unit includes an upper horizontal plane motor extending in the horizontal direction, and
the substrate processing system further comprises an upper horizontal transport robot, and the upper horizontal transport robot is configured to move in the horizontal direction while being magnetically levitated on the upper horizontal plane motor to transport at least one substrate between the upper horizontal transport robot and the stage of the lifting/lowering transport robot at the upper transport position.

19. The substrate processing system according to claim 18,
wherein the top portion of the lifting/lowering transport robot is configured to function as a part of the upper horizontal plane motor in a case where the lifting/lowering transport robot is at the standby position.

20. The substrate processing system according to claim 19,
wherein the at least one lower magnetic levitation type vacuum transport unit includes a lower horizontal plane motor extending in the horizontal direction, and
the substrate processing system further comprises a lower horizontal transport robot, and the lower horizontal transport robot is configured to move in the horizontal direction while being magnetically levitated on the lower horizontal plane motor to transport at least one substrate between the lower horizontal transport robot and the stage of the lifting/lowering transport robot at the lower transport position.
